(19) United States
(12) Patent Application Publication
(10) Pub. No.: US 2008/0076071 A1
(43) Pub. Date: Mar. 27, 2008

(54) Method of forming a fine pattern

(75) Inventors: Seok-Hyun Lim, Seoul (KR); Chang-Jin Kang, Seongnam-si (KR); Gyung-Jin Min, Seoul (KR); Seung-Pil Chung, Seoul (KR); Dong-Seok Lee, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/588,496

(22) Filed: Oct. 28, 2006

(30) Foreign Application Priority Data
Sep. 7, 2006 (KR) 2006-85943

(51) Int. Cl. G03F 7/00

(52) U.S. Cl. 430/311

(57) ABSTRACT

First, second and third layers are formed on a substrate for forming a fine pattern. A first mask pattern having a first space is formed on the third layer. A third layer pattern having a second space exposing the second layer is formed. A first sacrificial layer is formed on the second layer having the third layer pattern. A fourth layer is formed on the first sacrificial layer. A double mask pattern including the first and second mask patterns is formed using the second mask pattern in the second space. A second sacrificial layer is formed on the first sacrificial layer. A sacrificial layer pattern having a third space is formed by removing the double mask pattern, the third layer pattern, and a portion of the first sacrificial layer. An insulation layer pattern is formed by removing a portion of the first and second layers.

### CROSS-REFERENCE TO RELATED APPLICATION

This application claims priority under 35 USC §119 to Korean Patent Application No. 2006-85943 filed on Sep. 7, 2006, the contents of which are herein incorporated by reference.

### BACKGROUND OF THE INVENTION

1. Technical Field

The present disclosure relates to a method of forming a fine pattern in manufacturing a semiconductor device, and more particularly, to a method of forming a fine pattern using a double mask pattern including a first mask pattern and a second mask pattern in manufacturing a semiconductor device.

2. Discussion of the Related Art

A highly integrated semiconductor device can be manufactured by forming fine patterns using, for example, a self-alignment double patterning (SADP) process.

In forming the fine patterns using the SADP process, a double mask pattern including a first mask pattern and a second mask pattern is employed.

However, forming the fine patterns by the SADP process can be cumbersome. For example, when a bit line pad connecting a semiconductor substrate and a bit line is formed by the SADP process, the SADP process uses a large number of process steps and the double mask pattern employed in forming the fine patterns may become unstable because of a high aspect ratio of the double mask pattern. For example, the double mask pattern may collapse due to the high aspect ratio of the double mask pattern. Forming the double mask pattern that has a desired profile is also cumbersome.

### SUMMARY OF THE INVENTION

An exemplary embodiment of the present invention provides a method of forming a fine pattern in which a process for forming the fine pattern is simplified by reducing process steps and defect of the fine pattern is substantially decreased.

According to an exemplary embodiment of the present invention, a first layer, a second layer and a third layer are formed on a semiconductor substrate for forming a fine pattern. A first mask pattern having a first space can be formed on the third layer. The first space may partially expose the third layer. A third layer pattern having a second space configured to partially expose the second layer can be formed by removing a portion of the third layer exposed by the first space. A first sacrificial layer can be formed on a top surface of the first mask pattern, a sidewall and a bottom of the second space, and the second layer. The first sacrificial layer may have a substantially uniform thickness. A fourth layer can be formed on the first sacrificial layer. The fourth layer may form a second mask pattern. A double mask pattern including the first mask pattern and the second mask pattern can be formed by partially removing the fourth layer to form the second mask pattern filled in the second space. A second sacrificial layer can be formed on the first sacrificial layer having the double mask pattern. The second sacrificial layer may expose a top surface of the double mask pattern. A sacrificial layer pattern having a third space can be formed by removing the double mask pattern, the third layer pattern, and a first portion of the first sacrificial layer disposed beneath the second mask pattern. The third space partially can expose the second layer, and the sacrificial layer pattern includes a second portion of the first sacrificial layer and the second sacrificial layer. An insulation layer pattern can be formed by removing a third portion of the second layer and a fourth portion of the first layer. The third portion can be exposed by the third space, and the fourth portion can be disposed beneath the third portion.

According to an exemplary embodiment of the present invention, a first layer and a second layer are formed on a semiconductor substrate for forming a fine pattern. The first layer may have an etching selectivity with respect to the second layer. A third layer can be formed on the second layer having a thickness smaller than those of the first and the second layers. The third layer can have an etching selectivity with respect to the second layer.

A first mask pattern having a first space can be formed on the third layer. The first space partially may expose the third layer. A third layer pattern having a second space configured to partially expose the second layer can be formed by removing a portion of the third layer exposed by the first space. A first sacrificial layer can be formed on a top surface of the first mask pattern, a sidewall and a bottom of the second space, and the second layer. The first sacrificial layer may have an etching selectivity with respect to the first mask pattern and an etching ratio substantially the same as that of the first layer. A fourth layer can be formed on the first sacrificial layer. The fourth layer can form a second mask pattern having an etching ratio substantially the same as that of the first mask pattern.

A double mask pattern including the first mask pattern and the second mask pattern is formed by partially removing the fourth layer to form the second mask pattern filled in the second space. A preliminary second sacrificial layer can be formed on the first sacrificial layer. The preliminary second sacrificial layer can have an etching ratio substantially the same as that of the first sacrificial layer. A second sacrificial layer can be formed by removing the preliminary second sacrificial layer until the top surface of the double mask pattern is exposed. A sacrificial layer pattern having a third space can be formed by performing an etching process using an etching selectivity between the second sacrificial layer and the double mask pattern to remove the double mask pattern, the third layer pattern, and a first portion of the first sacrificial layer disposed beneath the second mask pattern. The third space partially can expose the second layer, and the sacrificial layer pattern may include a second portion of the first sacrificial layer and the second sacrificial layer.

A preliminary insulation layer pattern having a fourth space can be formed by performing an etching process using an etching selectivity between the second layer and the sacrificial layer pattern to remove a third portion of the second layer exposed by the third space. The fourth space partially may expose the first layer. An insulation layer pattern having a fifth space can be formed by performing an etching process using an etching selectivity between the preliminary insulation layer pattern and the first layer to remove a fourth portion of the first layer exposed by the fourth space. The fifth space partially can expose the semiconductor substrate.

According to an exemplary embodiment of the present invention, after the double mask pattern including the first and second mask patterns is formed, the double mask pattern can be removed prior to patterning the layers. Thus, the double mask pattern may not fall down. The double mask pattern may have a low aspect ratio that the double mask pattern may have a good profile. The bit line pad may be formed by uncomplicated processes, because a molding process to form the bit line pad in a conventional method may be omitted.

According to an exemplary embodiment of the present invention, the fine pattern may be formed using the double mask pattern and defect of the fine pattern may be substantially decreased, so that an exemplary embodiment of the present invention may be employed in manufacturing semiconductor devices.

### BRIEF DESCRIPTION OF THE DRAWINGS

Exemplary embodiments of the present disclosure can be understood in more detail from the following description taken in conjunction with the accompanying drawings in which:

FIGS. 1A to 1I are cross-sectional views illustrating a method of forming a fine pattern in accordance with an exemplary embodiment of the present invention; and

FIG. 2 is a plan view illustrating a fine pattern in accordance with an exemplary embodiment of the present invention.

### DESCRIPTION OF EXEMPLARY EMBODIMENTS

Exemplary embodiments of the present invention will be described below in more detail with reference to the accompanying drawings. The present invention may be embodied in many different forms and should not be construed as limited to the embodiments set forth herein.

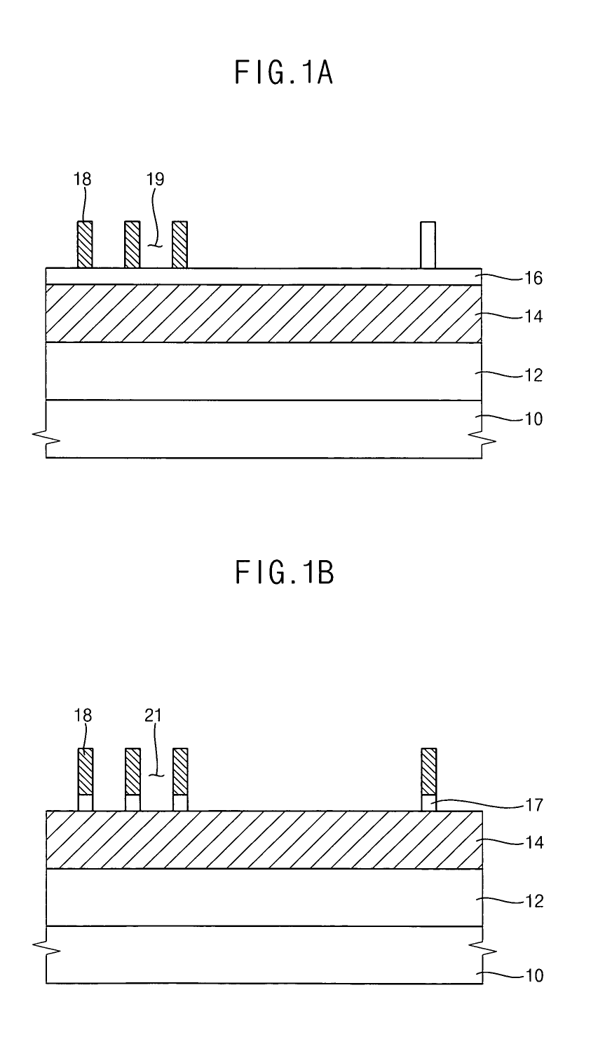

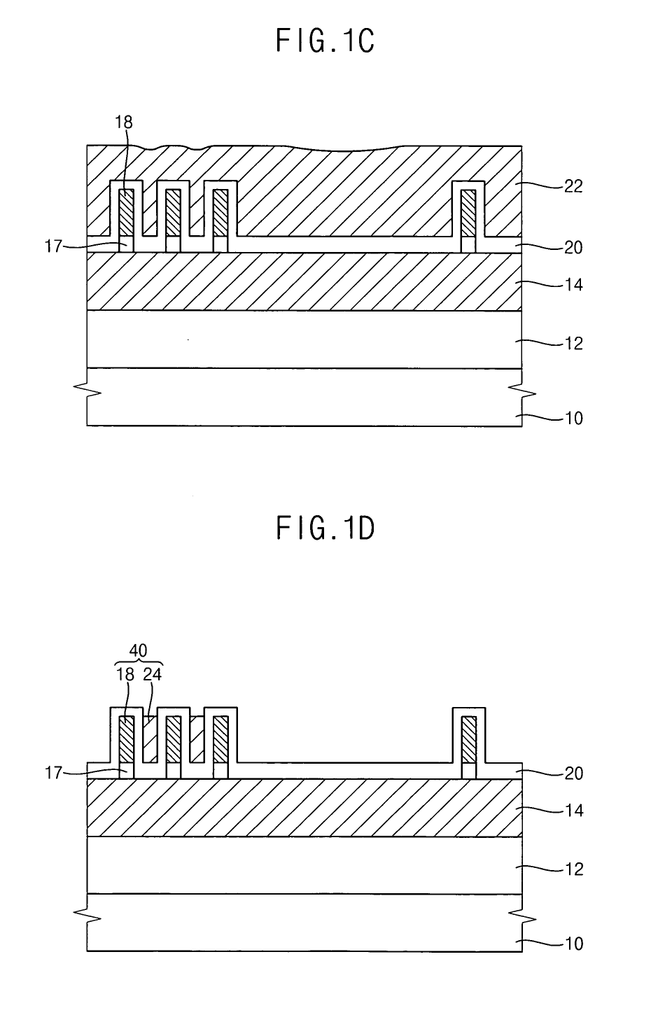

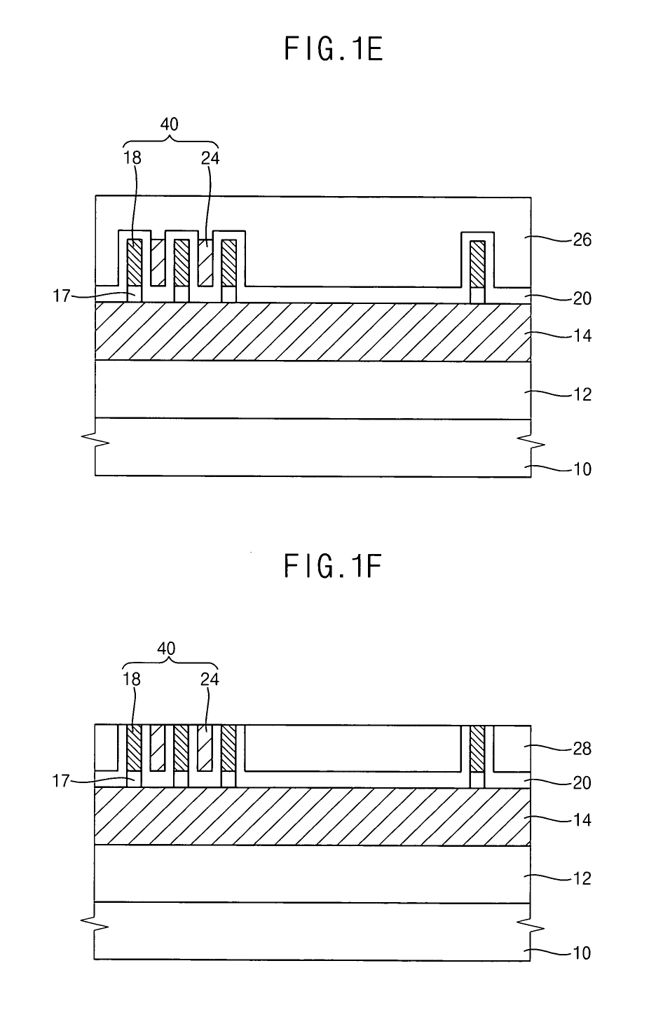

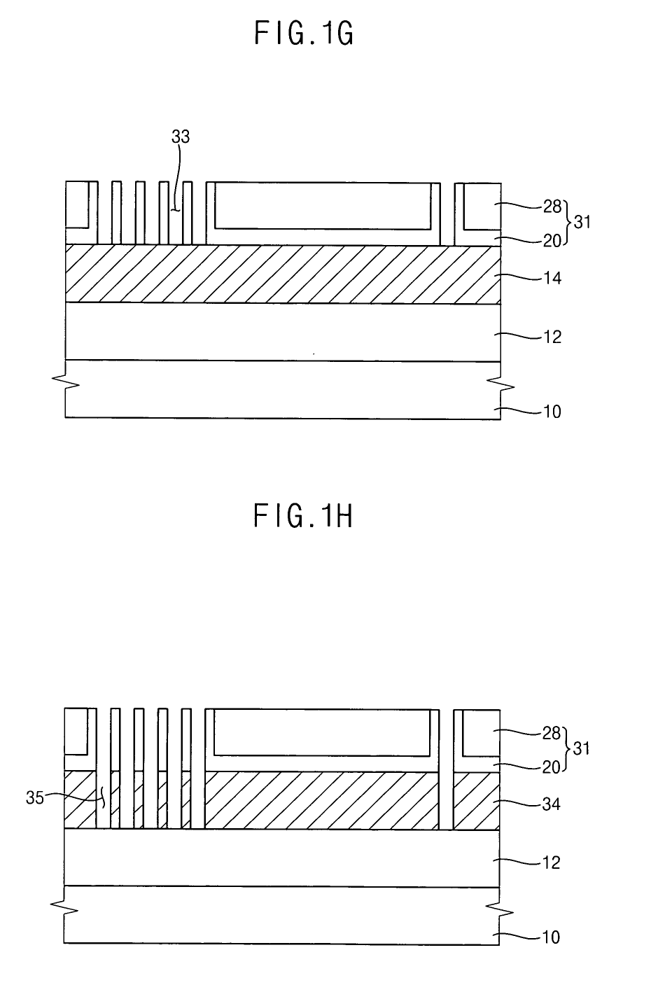

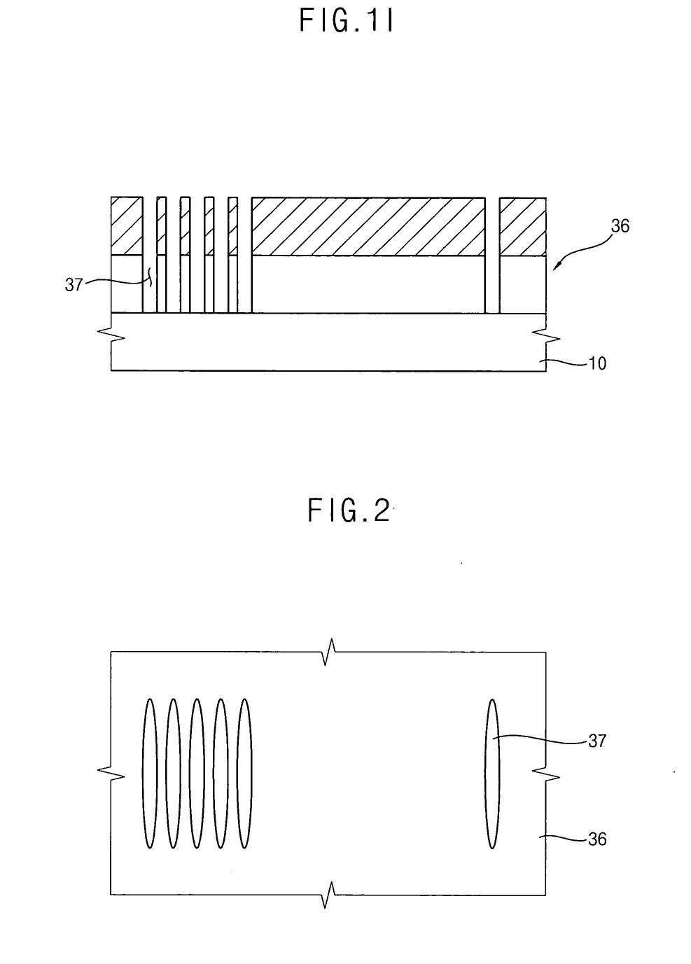

FIGS. 1A to 1I are cross-sectional views illustrating a method of forming a fine pattern in accordance with an exemplary embodiment of the present invention.

Referring to FIG. 1A, a first layer 12 and a second layer 14 are formed on a semiconductor substrate 10. The semiconductor substrate 10 may include, for example, a silicon substrate or a silicon-on-insulator (SOI) substrate. The first and the second layers 12 and 14 may be insulation layer patterns. In an exemplary embodiment of the present invention, the first and the second layers 12 and 14 may function as bit line pads (not shown), which connect a bit line and the semiconductor substrate 10. Thus, the first and the second layers 12 and 14 may have sufficient thicknesses such that the first and the second layers 12 and 14 may function as the bit line pads. The first layer 12 may have an etching selectivity with respect to the second layer 14 due to characteristics of successive processes. For example, the first layer 12 is formed using silicon oxide, and the second layer 14 is formed using polysilicon or a carbon-containing material.

A third layer 16 is formed on the second layer 14. The third layer 16 is formed to have a smaller thickness than other layers such as the first and the second layers 12, 14, because a portion of the third layer 16 may be removed in a successive process. The third layer 16 is formed to a thickness depending on a first sacrificial layer, which is formed in a subsequent process. The third layer 16 can be formed by an atomic layer deposition (ALD) process in which the thickness of the third layer 16 may be easily controlled. For example, the third layer 16 is formed using, for example, silicon oxide, silicon nitride, or any combination thereof.

A first mask pattern 18 having a first space 19, which partially exposes the third layer 16, is formed on the third layer 16. In an exemplary embodiment of the present invention, the first mask pattern 18 has a plurality of submask patterns each of which does not have a long linear shape but has an isolated form. Accordingly, the first space 19 may be defined to have spaces each of which has an isolated form between the sub-mask patterns. Each of second through fifth spaces may also have an isolated form. The first mask pattern 18 may have such an isolated form because a bit line pad, which has a shape corresponding to that of the first mask pattern 18, may be formed in accordance with exemplary embodiments of the present invention.

The first mask pattern 18 may be removed by a successive process, for example, by an etching process using an etching selectivity with respect to a first sacrificial layer. Thus, the first mask pattern 18 is formed, for example, using polysilicon. The first mask pattern 18 may be formed by a photolithography process.

Referring to FIG. 1B, a portion of the third layer 16, which is not covered with the first mask pattern 18, is removed by an etching process using the first mask pattern 18 as an etching mask. Thus, the third layer 16 is converted into a third layer pattern 17, having a portion of a second space 21, which partially exposes the second layer 14. The second space 21 is formed through not only the third layer pattern 17 but also the first mask pattern 18. That is, the second space 21 is defined to have the first space 19 therein.

A second mask pattern has a thickness and a width substantially the same as those of the first mask pattern 18. Thus, the second space 21 has a depth and a width in accordance with the thickness and the width of the second mask pattern. The first space 19 is formed such that the first mask pattern 18 may have a desirable thickness and a width in accordance with the thickness and the width of the second mask pattern.

Referring to FIG. 1C, a first sacrificial layer 20 is formed on the second layer 14 on which the third layer pattern 17 and the first mask pattern 18 are stacked. That is, the first sacrificial layer 20 is continuously formed to have a substantially uniform thickness on a top surface of the first mask pattern 18, a sidewall and a bottom of the second space 21, and the second layer 14. The first sacrificial layer 20 is formed by, for example, an atomic layer deposition (ALD) process. The ALD process may have a good step coverage compared to a process such as a chemical vapor deposition (CVD) process or a sputtering process. The first sacrificial layer 20 has a thickness substantially the same as that of the third layer 16, because the third layer pattern 17 together with the first sacrificial layer 20 may be partially removed in a successive process for forming a first sacrificial layer pattern.

The first sacrificial layer 20 has an etching selectivity with respect to the first mask pattern 18. The first sacrificial layer 20 has an etching ratio substantially the same as that of the first layer 12. For example, the first sacrificial layer 20 is formed using silicon oxide. Thus, in an exemplary embodiment of the present invention, the first sacrificial layer 20 may be formed using silicon oxide by an ALD process.

A fourth layer 22 configured to form a second mask pattern is formed on the first sacrificial layer 20 to sufficiently fill the second space 21. The fourth layer 22 together with the first mask pattern 18 are formed into a double mask pattern, so that the fourth layer 22 may have an etching ratio substantially the same as that of the first mask pattern 18. Thus, the fourth layer 22 may be formed using, for example, polysilicon.

Referring to FIG. 1D, the fourth layer 22 is partially removed so that only a portion of the fourth layer 22 disposed in the second space 21 may remain on the first sacrificial layer 20. When partially removing the fourth layer 22, a top surface of the first sacrificial layer 20 may be exposed. The fourth layer 22 may be partially removed by, for example, an etch-back process or an isotropic etching process. When the fourth layer 22 is partially removed by an anisotropic etching process, a side well (not shown) on a sidewall of the first mask pattern 18 may be generated. Thus, in an exemplary embodiment of the present invention, the isotropic etching process is performed to partially remove the fourth layer 22, thereby hindering generation of the side well on the sidewall of the first mask pattern 18.

A second mask pattern 24 is formed so that a double mask pattern 40 including the first and the second mask patterns 18 and 24 may be formed on the third layer pattern 17 and the first sacrificial layer 20. That is, the double mask pattern 40 is formed by an SADP process.

Referring to FIG. 1E, a preliminary second sacrificial layer 26 is formed on the first sacrificial layer 20 to sufficiently cover the double mask pattern 40. The preliminary second sacrificial layer 26 has an etching ratio substantially the same as that of the first sacrificial layer 20, because the preliminary second sacrificial layer 26 together with the first sacrificial layer 20 are partially removed to form a sacrificial layer pattern. For example, the preliminary second sacrificial layer 26 is formed using silicon oxide.

Referring to FIG. 1F, the preliminary second sacrificial layer 26 is partially removed. In an exemplary embodiment of the present invention, the preliminary second sacrificial layer 26 is partially removed until a top surface of the double mask pattern 40 is exposed. The preliminary second sacrificial layer 26 may be partially removed by, for example, a chemical mechanical polishing (CMP) process, an etch-back process or a combined process of a CMP and an etch-back. In an exemplary embodiment of the present invention, the preliminary second sacrificial layer 26 is partially removed by the CMP process.

The preliminary second sacrificial layer 26 is partially removed, so that a remaining portion of the preliminary second sacrificial layer 26 may be converted into a second sacrificial layer 28.

Referring to FIG. 1G, the double mask pattern 40, of which the top surface is exposed after forming the second sacrificial layer 28, is removed. The double mask pattern 40 may be removed by an etching process using an etching selectivity with respect to the first sacrificial layer 20. The second sacrificial layer 28 has an etching ratio substantially the same as that of the first sacrificial layer 20 so that only the double mask pattern 40 may be removed according to the above etching selectivity.

The third layer pattern 17 and a first portion of the first sacrificial layer 20, which are disposed beneath the first mask pattern 18 and the second mask pattern 24, respectively, may remain after the double mask pattern 40 is removed. In an exemplary embodiment of the present invention, the third layer pattern 17 and the first portion of the first sacrificial layer 20 are also removed when the double mask pattern 40 is removed.

The third layer pattern 17 and the first sacrificial layer 20 may include silicon oxide similar to the second sacrificial layer 28, so that a top surface of the second sacrificial layer 28 may be removed while the third layer pattern 17 and the first portion of first sacrificial layer 20 are removed. The third layer pattern 17 and the first sacrificial layer 20 are formed to have a smaller thickness than other layers, so that a removal of the top surface of the second sacrificial layer 28 may be trivial. The third layer pattern 17 and the first sacrificial layer 20 may have substantially the same thickness, thereby being removed almost simultaneously.

The double mask pattern 40, the third layer pattern 17 and the first portion of the first sacrificial layer 20 are removed to form a sacrificial layer pattern 31 having a third space 33. That is, the sacrificial layer pattern 31 includes a second portion of the first sacrificial layer 20, which remains on the second layer 14, and the second sacrificial layer 28. The third space 33 is formed at positions in which the double mask pattern 40, the third layer pattern 17 and the first portion of the first sacrificial layer 20 has been disposed. Thus, the third space 33 may include subspaces each of which has an isolated form similar to the first space 19 or the second space 21.

Referring to FIG. 1H, a portion of the second layer 14, which is exposed by the third space 33 of the sacrificial layer pattern 31, is removed by an etching process using an etching selectivity with respect to the sacrificial layer pattern 31. In an exemplary embodiment of the present invention, the sacrificial layer pattern 31 includes silicon oxide and the second layer 14 includes polysilicon. Thus, the portion of the second layer 14 may be removed by an etching process using an etching selectivity between silicon oxide and polysilicon. The portion of the second layer 14 may be removed until a top surface of the first layer 12 is exposed.

The second layer 14 is partially removed to form a preliminary insulation layer pattern 34 having a fourth space 35 therein, which partially exposes the first layer 12. The fourth space 35 is connected to the third space 33, thereby including sub-spaces each of which has an isolated form.

Referring to FIG. 1I, a portion of the first layer 12, which is exposed by the fourth space 35 of the preliminary insulation layer pattern 34, is removed by an etching process using an etching selectivity with respect to the second layer 14. In an exemplary embodiment of the present invention, the first layer 12 includes silicon oxide and the second layer 14 includes polysilicon. Thus, the portion of the first layer 12 may be removed by an etching process using an etching selectivity between silicon oxide and polysilicon. The portion of the first layer 12 may be removed until a top surface of the semiconductor substrate 10 is exposed.

The first layer 12 is partially removed to form an insulation layer pattern 36 having a fifth space 37, which partially exposes the semiconductor substrate 10, together with the preliminary insulation layer pattern 34. The fifth space 37 is defined to include the fourth space 35 therein, thereby forming a long enough space for exposing the semiconductor substrate 10. The fifth space 37 may include sub-spaces each of which has an isolated form. The sacrificial layer pattern 31 may be also removed when the first layer 12 is partially removed, because the sacrificial layer pattern 31 may have an etching ratio substantially the same as that of the first layer 12.

According to an exemplary embodiment of the present invention, a fine pattern having a high aspect ratio may be formed in a simplified process. A bit line pad (not shown) having a higher aspect ratio may be formed by increasing thicknesses of the first and the second layers 12 and 14.

A bit line pad having an isolated form as shown in FIG. 2 may be formed in a simplified process. Each of the first through the fifth spaces 19, 21, 33, 35 and 37 may have an isolated form, so that the bit line pad having the isolated form may be formed by filling the fifth space 37 with a conductive material.

The first, second and third layers 12, 14 and 16, the double mask pattern 40, and the sacrificial pattern 32 may be formed using a material, which is not included in the above-mentioned materials but satisfies the above-mentioned etching selectivity conditions.

According to an exemplary embodiment of the present invention, a double mask pattern does not fall down in a process for forming a fine pattern, because the double mask pattern is removed before the double mask pattern becomes a high aspect ratio pattern. Additionally, the process to form the fine pattern using the double mask pattern may be simplified by omitting a molding process.

Thus, a method of forming the fine pattern in accordance with exemplary embodiments of the present invention may be employed in manufacturing a semiconductor device.

Although exemplary embodiments have been described herein with reference to the accompanying drawings, it is to be understood that the present invention is not limited to these precise embodiments but various changes and modifications can be made by one skilled in the art without departing from the spirit and scope of the present invention. All such changes and modifications are intended to be included within the scope of the invention as defined by the appended claims.

What is claimed is:

1. A method of forming a fine pattern, the method comprising:
forming a first layer, a second layer and a third layer on a semiconductor substrate;
forming a first mask pattern having a first space on the third layer, wherein the first space is configured to partially expose the third layer;
forming a third layer pattern having a second space configured to partially expose -the second layer by removing a portion of the third layer exposed by the first space;
forming a first sacrificial layer on a top surface of the first mask pattern, a sidewall and a bottom of the second space, and the second layer, wherein the first sacrificial layer is configured to have a substantially uniform thickness;
forming a fourth layer on the first sacrificial layer, wherein the fourth layer is configured to form a second mask pattern;
forming a double mask pattern including the first mask pattern and the second mask pattern by partially removing the fourth layer to form the second mask pattern filled in the second space;
forming a second sacrificial layer on the first sacrificial layer having the double mask pattern, wherein the second sacrificial layer is configured to expose a top surface of the double mask pattern;
forming a sacrificial layer pattern having a third space by removing the double mask pattern, the third layer pattern, and a first portion of the first sacrificial layer disposed beneath the second mask pattern, wherein the third space partially exposes the second layer, and the sacrificial layer pattern includes a second portion of the first sacrificial layer and the second sacrificial layer; and
forming an insulation layer pattern by removing a third portion of the second layer and a fourth portion of the first layer, wherein the third portion of the second layer is exposed by the third space and the fourth portion of the first layer is disposed beneath the third portion.

2. The method of claim 1, wherein the first layer and the first and the second sacrificial layers have substantially the same etching ratio, and the second layer has an etching selectivity with respect to the first layer.

3. The method of claim 1, wherein the third layer has a thickness substantially the same as that of the first sacrificial layer.

4. The method of claim 3, wherein the third layer and the first sacrificial layer are formed by an atomic layer deposition (ALD) process.

5. The method of claim 1, wherein the first layer and the first and the second sacrificial layers include silicon oxide and the second layer includes polysilicon.

6. The method of claim 1, wherein the third layer includes at least one of silicon nitride and silicon oxide.

7. The method of claim 1, the first and the second mask patterns include polysilicon.

8. The method of claim 1, wherein forming the second sacrificial layer comprises:
forming a preliminary second sacrificial layer on the first sacrificial layer to cover the double mask pattern; and
removing the preliminary second sacrificial layer until the top surface of the double mask pattern is exposed.

9. A method of forming a fine pattern, the method comprising:
forming a first layer and a second layer on a semiconductor substrate;
forming a third layer on the second layer having a thickness smaller than those of the first and the second layers;
forming a first mask pattern having a first space on the third layer, wherein the first space is configured to partially expose the third layer;
forming a third layer pattern having a second space configured to partially expose the second layer by removing a portion of the third layer exposed by the first space;
forming a first sacrificial layer on a top surface of the first mask pattern, a sidewall and a bottom of the second space, and the second layer;
forming a fourth layer on the first sacrificial layer, wherein the fourth layer is configured to form a second mask pattern having an etching ratio substantially the same as that of the first mask pattern;
forming a double mask pattern including the first mask pattern and the second mask pattern by partially removing the fourth layer to form the second mask pattern filled in the second space;
forming a preliminary second sacrificial layer on the first sacrificial layer;
forming a second sacrificial layer by removing the preliminary second sacrificial layer until the top surface of the double mask pattern is exposed;
forming a sacrificial layer pattern having a third space by performing an etching process using an etching selectivity between the second sacrificial layer and the double mask pattern to remove the double mask pattern, the third layer pattern, and a first portion of the first sacrificial layer disposed beneath the second mask pattern, wherein the third space partially exposes the second layer, and the sacrificial layer pattern includes a second portion of the first sacrificial layer and the second sacrificial layer;
forming a preliminary insulation layer pattern having a fourth space by performing an etching process using an etching selectivity between the second layer and the sacrificial layer pattern to remove a third portion of the second layer exposed by the third space, wherein the fourth space partially exposes the first layer; and
forming an insulation layer pattern having a fifth space by performing an etching process using an etching selectivity between the preliminary insulation layer pattern and the first layer to remove a fourth portion of the first layer exposed by the fourth space, wherein the fifth space partially exposes the semiconductor substrate.

10. The method of claim 9, wherein the third layer and the first sacrificial layer have substantially the same thickness and are formed by an atomic layer deposition (ALD) process.

11. The method of claim 9, wherein the first layer and the first and the second sacrificial layers include silicon oxide, the second layer and the first and the second mask patterns include polysilicon, and the third layer includes at least one of silicon nitride and silicon oxide.

12. The method of claim 9, wherein the first layer is configured to have an etching selectivity with respect to the second layer.

13. The method of claim 9, wherein the third layer is configured to have an etching selectivity with respect to the second layer.

14. The method of claim 9, wherein the first sacrificial layer is configured to have an etching selectivity with respect to the first mask pattern and an etching ratio substantially the same as that of the first layer.

15. The method of claim 9, wherein the preliminary second sacrificial layer is configured to have an etching ratio substantially the same as that of the first sacrificial layer.
